(19) United States
(12) Patent Application Publication
(10) Pub. No.: US 2023/0408927 A1
(43) Pub. Date: Dec. 21, 2023

(54) APPARATUS AND METHOD OF LASER INTERFERENCE LITHOGRAPHY

(71) Applicant: The University of Hong Kong, Hong Kong (HK)

(72) Inventors: Wendi LI, Hong Kong (HK); Zhuofei GAN, Hong Kong (HK); Siyi MIN, Shenzhen (CN)

(21) Appl. No.: 18/250,542

(22) PCT Filed: Nov. 16, 2021
(86) PCT No.: PCT/CN2021/130888

§ 371 Date: Apr. 26, 2023

(30) Foreign Application Priority Data
Nov. 16, 2020 (CN) 202011282106.7

(51) Int. Cl. G03F 7/00

(52) U.S. Cl. CPC G03F 7/70408; G03F 7/70133

(57) ABSTRACT

Provided is a method of laser interference lithography, including: performing an interference exposure on a wafer coated with a photoresist; and performing a patterned flood exposure on the interference-exposed wafer, wherein the performing the flood exposure includes: determining a first light field distribution in the interference-exposed wafer; determining a light field distribution of the floodlight source as a second light field distribution based on the first light field distribution, an expected pattern distribution, and parameters of the floodlight source used for the flood exposure; and patterning the light field distribution of the floodlight source based on the second light field distribution, and controlling the floodlight source having the patterned light field distribution to perform the flood exposure on the interference-exposed wafer, so as to form the expected pattern distribution in the flood-exposed wafer.

### TECHNICAL FIELD

The present disclosure relates to a field of lithography, and in particular, to an apparatus and a method of laser interference lithography.

### BACKGROUND

Interferometric lithography is a technique for patterning an array of sub-micron structures that cover a large area. The interference of two or more beams of coherent light waves is recorded onto a photoresist to produce a plurality of regular periodic patterns of structures, including gratings, holes, pillars, cones, and lattices. When a coherent laser beam is divided into two or more beams, and then combined and overlapped in a certain region, a regular light intensity pattern of a grating or light spot may be formed. A photoresist material is exposed through these light intensity patterns, and an interference pattern is recorded after development. The lithography technique allows for maskless patterning of a large area substrate using a shorter exposure time. Interference lithography may generate periodic nanostructures on a large area with high productivity and low cost, and thus plays an important role in emerging energy, sensing, luminescence, and other applications.

Generally, interference lithography may generate a periodic pattern through two different solutions, namely, Lloyd mirror structure and dual-beam holographic imaging structure. However, when using interference lithography to prepare a periodic nano pattern, there is often a problem that a duty cycle of a photoresist pattern exposed to an interference pattern is uneven due to an uneven exposure field of a light source used, thereby reducing a process accuracy of a product. In addition, in many applications, it is necessary to obtain a pattern having a duty cycle distribution that varies with position, such as a pattern with a linear change in duty cycle. Such requirements are often difficult to obtain by an exposure light field of interference lithography. Therefore, it is difficult to meet such requirements for interference lithography equipment with high productivity and low cost.

Therefore, there is a need for an apparatus and a method of laser interference lithography that may provide an expected lithographic pattern, wherein the apparatus and the method of laser interference lithography may provide the expected lithographic pattern with high accuracy without significantly increasing a complexity and manufacturing cost of the apparatus.

### SUMMARY OF THE INVENTION

The objective of the present disclosure is to solve at least some or all of the above-mentioned problems.

An aspect of the present disclosure provides an apparatus of laser interference lithography, including: a dual-beam or multi-beam laser interference lithography device configured to perform an interference exposure on a wafer coated with a photoresist; a floodlight source having a patternable light field distribution and configured to perform a patterned flood exposure on the interference-exposed wafer; and a controller configured to: determine a first light field distribution in the interference-exposed wafer; determine a light field distribution of the floodlight source as a second light field distribution based on the first light field distribution, an expected pattern distribution, and parameters of the floodlight source; and pattern the light field distribution of the floodlight source based on the second light field distribution, and control the floodlight source having the patterned light field distribution to perform the patterned flood exposure on the interference-exposed wafer, so as to form the expected pattern distribution in the flood-exposed wafer.

In an example, the floodlight source further includes a defocusing module configured to defocus light emitted by the floodlight source to form a flooded blurred spot.

In another example, the floodlight source further includes a motor configured to move the floodlight source slightly to form a flooded blurred spot.

In another example, the floodlight source further includes a light field patterning module, wherein the controller is further configured to pattern the light field distribution of the floodlight source via the light field patterning module into the second light field distribution.

In another example, the apparatus of laser interference lithography further includes a developing unit configured to develop the flood-exposed wafer.

In another example, a patterned floodlight source is implemented using a grayscale image from a UV projector, wherein different grayscale values in the grayscale image represent different light intensities.

In another example, the first light field distribution is an ideal interference pattern, and the second light field distribution is a uniform distribution.

In another example, the first light field distribution is an ideal interference pattern, and the second light field distribution is a stepped distribution.

Another aspect of the present disclosure provides a method of laser interference lithography, including: performing an interference exposure on a wafer coated with a photoresist; and performing a patterned flood exposure on the interference-exposed wafer, wherein the performing a patterned flood exposure includes: determining a first light field distribution in the interference-exposed wafer; determining a light field distribution of the floodlight source as a second light field distribution based on the first light field distribution, an expected pattern distribution, and parameters of the floodlight source used for the patterned flood exposure; and patterning the light field distribution of the floodlight source based on the second light field distribution, and controlling the floodlight source having the patterned light field distribution to perform the patterned flood exposure on the interference-exposed wafer, so as to form the expected pattern distribution in the flood-exposed wafer.

In an example, the method of laser interference lithography further includes: performing a development processing on the flood-exposed wafer.

In another example, the determining a first light field distribution includes: developing an interference-exposed sample; detecting a profile of the developed wafer through a scanning electron microscope; and determining the first light field distribution in the interference-exposed wafer based on the detected profile.

In another example, the determining the second light field distribution may include: determining to apply a higher flood exposure dose at a location with a smaller first light field distribution and to apply a lower flood exposure dose at a location with a larger first light field distribution, in response to determining the expected pattern distribution to be a periodic pattern with a uniform duty cycle.

In another example, the determining the second light field distribution may include: determining the second light field distribution in response to determining the expected pattern distribution to be a pattern distribution having a spatially modulated duty cycle, so that the pattern distribution having the spatially modulated duty cycle is formed in the flood-exposed wafer.

In another embodiment, a patterned floodlight source is implemented using a grayscale image from a UV projector, wherein different grayscale values in the grayscale image represent different light intensities.

In another embodiment, the first light field distribution is an ideal interference pattern, and the second light field distribution is a uniform distribution.

In another embodiment, the first light field distribution is an ideal interference pattern, and the second light field distribution is a stepped distribution.

### BRIEF DESCRIPTION OF THE DRAWINGS

FIG. 1 shows an architecture of a fiber type dual-beam laser interference lithography device according to exemplary embodiments of the present disclosure.

FIG. 2A to FIG. 2C show a conceptual schematic diagram of an apparatus of laser interference lithography according to exemplary embodiments of the present disclosure.

FIG. 3 shows an architecture diagram of an apparatus of laser interference lithography according to exemplary embodiments of the present disclosure.

FIG. 4 shows a flowchart of a method of laser interference lithography according to exemplary embodiments of the present disclosure.

FIG. 5 shows a flowchart of a flood exposure process according to exemplary embodiments of the present disclosure.

FIG. 6 shows a grating-like structure having a period of, for example, 1 μm formed using an apparatus and a method of laser interference lithography according to exemplary embodiments of the present disclosure.

FIG. 7 shows a sample diagram of a pattern having a spatially modulated duty cycle fabricated on a 3-inch sample using an apparatus and a method of laser interference lithography according to exemplary embodiments of the present disclosure.

FIG. 8 shows an example of obtaining a grating-like structure having uniform line width on a large size wafer using a method and apparatus according to exemplary embodiments of the present disclosure.

FIG. 9 shows an example of spatially modulating a filling rate of a two-dimensional nanostructure using a method and apparatus according to exemplary embodiments of the present disclosure.

### DETAILED DESCRIPTION OF EMBODIMENTS

Embodiments of the present disclosure will be described below with reference to the accompanying drawings. It should be understood, however, that these descriptions are merely exemplary and are not intended to limit the scope of the present disclosure. In the following detailed descriptions, for purposes of explanation, numerous specific details are set forth in order to provide a thorough understanding of embodiments of the present disclosure. It is obvious, however, that one or more embodiments may be implemented without these specific details. In addition, in the following descriptions, descriptions of well-known structures and technologies are omitted to avoid unnecessarily obscuring the concept of the present disclosure.

Terms used herein are for the purpose of describing embodiments only and are not intended to limit the present disclosure. Terms “comprising”, “including” and the like used herein specify a presence of the feature, step, operation and/or component, but do not preclude a presence or addition of one or more other features, steps, operations or components.

All terms (including technical and scientific terms) used herein have the meaning as commonly understood by those skilled in the art, unless otherwise defined. It should be noted that the terms used herein should be construed to have meanings consistent with the context of the present description and should not be construed in an idealized or overly rigid manner.

Where expressions like “at least one of A, B, and C, etc.” are used, they should generally be interpreted in accordance with the meaning of the expression as commonly understood by those skilled in the art (e.g., “a system having at least one of A, B and C” should include, but not be limited to, a system having A alone, having B alone, having C alone, having A and B, having A and C, having B and C, and/or having A, B, C, etc.). Where expressions like “at least one of A, B, or C, etc.” are used, they should generally be interpreted in accordance with the meaning of the expressions as commonly understood by those skilled in the art (e.g., “a system having at least one of A, B or C” should include, but not be limited to, a system having A alone, having B alone, having C alone, having A and B, having A and C, having B and C, and/or having A, B, C, etc.).

In the accompanying drawings, the same or similar reference signs denote the same or similar structures.

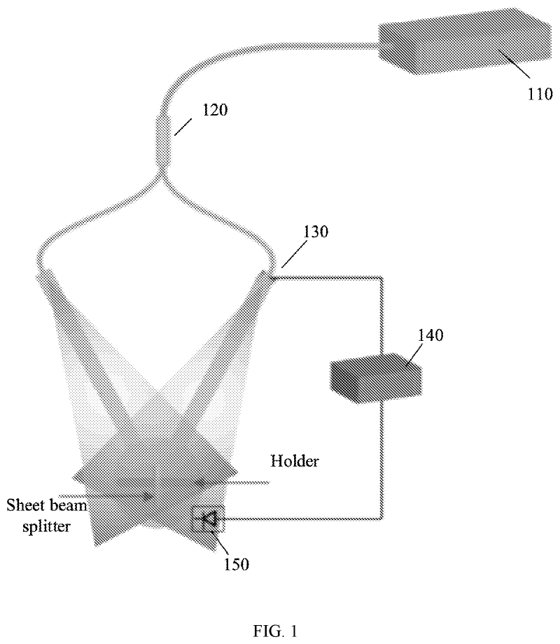

FIG. 1 shows an architecture of a fiber type dual-beam laser interference lithography device according to exemplary embodiments of the present disclosure.

Specifically, the fiber type dual-beam laser interference lithography device according to exemplary embodiments of the present disclosure includes a laser source 110 and a fiber beam splitter 120. The laser source 110 may be a single-frequency ultraviolet laser that outputs a highly-coherent single-frequency ultraviolet light. For example, a wavelength of laser source 110 may be 266 nm, 351 nm, 355 nm, 360 nm, or other ultraviolet or near ultraviolet wavelengths. The highly-coherent single-frequency ultraviolet light is output to the fiber beam splitter 120 through a single mode polarization maintaining fiber (PMF). In an embodiment, the fiber beam splitter 120 may also be polarization-maintained and used to divide the input highly-coherent single-frequency ultraviolet light into at least two sub-laser beams. Then at least two sub-beams form an interference pattern to perform an interference exposure on a wafer located on an operating platform and held by, for example, a holder.

In addition, the fiber type dual-beam laser interference lithography device may additionally include a controller 140, a photodetector 150, an actuator 130, and a sheet beam splitter. As shown in FIG. 1, the actuator 130 such as a piezoelectric ceramic may be located on at least one branch of the fiber beam splitter 120, so that the controller 140 may control the actuator 130 to change a phase of a sub-beams on the branch where the actuator is located, to change an interference pattern, based on a detection of the interference pattern by the photodetector 150.

The fiber type dual-beam laser interference lithography device shown in FIG. 1 will be used as an example of a dual-beam or multi-beam laser interference lithography device. However, it should be clear that the concept of the present disclosure is not only applicable to the fiber type dual-beam laser interference lithography device shown in FIG. 1, but also applicable to Lloyd's mirror structure and other dual-beam or multi-beam laser interference lithography devices.

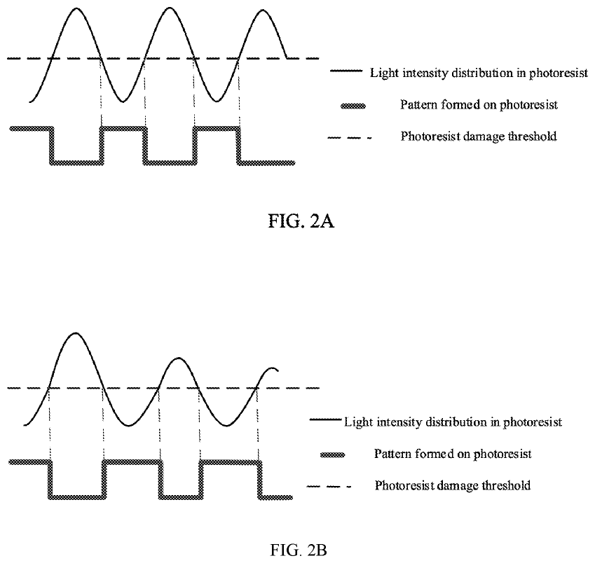

FIG. 2A to FIG. 2C show a conceptual schematic diagram of an apparatus of laser interference lithography according to exemplary embodiments of the present disclosure. FIG. 2A to FIG. 2C show schematic diagrams of periodic patterns generated under an ideal interference pattern, an actual interference pattern that has not been subjected to flood exposure processing, and a compensated interference pattern that has been subjected to flood exposure compensation using a positive photoresist as an example.

As shown in FIG. 2A, in an ideal situation, the interference pattern has perfect periodicity. At this point, due to the use of positive photoresist, the photoresist is washed away at a location where the expose dose for light distribution is higher than a photoresist damage threshold dose. In this way, a pattern having the perfect periodicity may be constructed. However, due to the uneven exposure light field (usually a Gaussian beam), the duty cycle of the photoresist pattern after exposure of the interference pattern may be uneven, as shown in FIG. 2B.

In order to overcome the above-mentioned problems, the present disclosure proposes using a patterned flood exposure after an interference exposure to compensate for a process error in manufacturing a device caused by an uneven light field of interference exposure, e.g., a problem of an uneven duty cycle of a periodic device. Specifically, after the exposure of the interference pattern shown in FIG. 2B, a patterned flood exposure, or flood exposure for short, may be performed using a floodlight source with an emission wavelength within a sensitive wavelength range of the photoresist, to compensate for the uneven light field of interference exposure. Specifically, the light field distribution of the floodlight source may be designed, so that a cumulative exposure dose distribution in the flood-exposed wafer may exhibit a pattern having a uniform duty cycle, as shown in FIG. 2C. Alternatively, further, the light field distribution of the floodlight source is designed so that the cumulative exposure dose distribution in the flood-exposed wafer may exhibit an expected light field distribution, thereby obtaining an expected lithography pattern. In other words, by adopting a method of compensating the interference exposure by patterned flood exposure, not only a periodic structure with uniform duty cycle may be obtained, but also a spatially modulated duty cycle distribution may be obtained, such as obtaining a linear change in the duty cycle within a certain range, a periodic change in the duty cycle, a radial change in the duty cycle, or even any given pattern. The patterned secondary exposure may be achieved through UV projection exposure, UV lithography with a mask, and directional laser writing. It should also be noted that although FIG. 2A to FIG. 2C show the inventive concept of the present disclosure with the positive photoresist as an example, the present disclosure is not limited this. The present disclosure may also be applied to various types of photoresists such as a negative photoresist and a reverse photoresist.

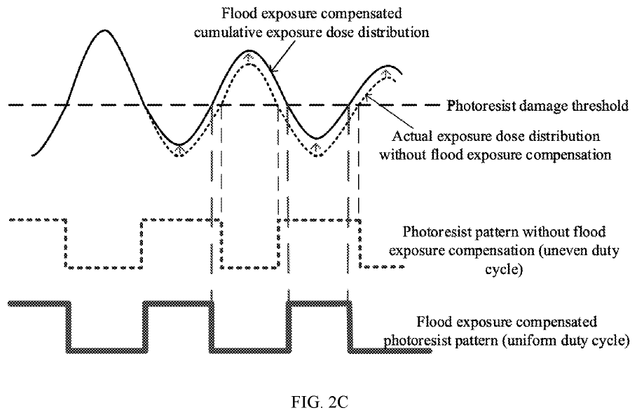

The device and the method of laser interference lithography according to exemplary embodiments of the present disclosure are described below with reference to FIG. 3 to FIG. 5.

Specifically, FIG. 3 shows an architecture diagram of an apparatus of laser interference lithography according to exemplary embodiments of the present disclosure. As shown in FIG. 3, the apparatus of laser interference lithography according to exemplary embodiments of the present disclosure includes a dual-beam or multi-beam laser interference lithography device 310, a floodlight source 320, and a controller 330. Specifically, the dual-beam or multi-beam laser interference lithography device 310 is used to perform a laser interference exposure of a sample wafer coated with a photoresist. The controller 330 may determine a first light field distribution in the interference-exposed wafer; determine a light field distribution of the floodlight source as a second light field distribution based on the first light field distribution, an expected pattern distribution, and parameters of the floodlight source 320 (such as wavelength, power, etc.); and pattern the light field distribution of the floodlight source based on the second light field distribution, and control the floodlight source having the patterned light field distribution to perform patterned flood exposure on the interference-exposed wafer, so as to form the expected pattern distribution in the flood-exposed wafer.

The dual-beam or multi-beam laser interference lithography device 310 may be implemented using, for example, a fiber type dual-beam or multi-beam laser interference lithography device as shown in FIG. 1, which may be configured to perform the interference exposure on a wafer coated with a photoresist. For example, the dual-beam or multi-beam laser interference lithography device 310 may include a laser light source configured to emit highly-coherent ultraviolet/near ultraviolet single-frequency light (e.g., at a wavelength of 405 nm); an input coupling fiber configured to couple a coherent laser beam from a laser light source to a fiber beam splitter; and the fiber beam splitter configured to divide the coherent laser beam from the input coupling fiber into at least two sub-laser beams, and output the sub-laser beams through two or more output coupling fibers, thereby performing the interference exposure on the wafer coated with the photoresist.

The floodlight source 320 may have a patternable light field distribution and be configured to perform the patterned flood exposure on the interference-exposed wafer, i.e., to expose the wafer using a patterned flooded light spot. Specifically, the floodlight source 320 may include a defocusing module, wherein the defocusing module may be implemented by a defocusing optical device and configured to defocus light (e.g., out of focus) emitted by the floodlight source to form a flooded blurred spot. Alternatively, the floodlight source 320 may optionally include a motor configured to move the floodlight source slightly to form a flooded fuzzy spot. In addition, the floodlight source 320 may typically include a light field patterning module such as a spatial light modulator for forming a patterned grayscale light field distribution. Since different gray values on a digital grayscale image represent different light intensities on a projection pattern, patterned flood exposure may be performed based on the grayscale image. In addition, the floodlight source 320 may have the same or different wavelengths as the laser light sources included in the dual-beam or multi-beam laser interference lithography device 310, as long as both are within a sensitive wavelength range of the photoresist. In the example, 405 nm or 365 nm may be selected as a wavelength of the floodlight source.

The controller 330 may be implemented as one or more processing modules. The one or more processing modules may determine the first light field distribution in the interference-exposed wafer. In an embodiment, the determining the first light field distribution may include developing an interference-exposed sample using a developing device; detecting a profile of the developed wafer through a detection instrument such as a scanning electron microscope; and determining the first light field distribution in the interference-exposed wafer based on the detected profile.

After determining the first light field distribution, the controller 330 may further determine a light field distribution of the floodlight source as a second light field distribution based on the determined first light field distribution, an expected pattern distribution, and parameters of the floodlight source; and pattern the light field distribution of the floodlight source based on the determined second light field distribution, and control the floodlight source 320 having the patterned light field distribution to perform patterned flood exposure on the interference-exposed wafer, so as to form the expected pattern distribution in the flood-exposed wafer. For example, as shown in FIG. 2A to FIG. 2C, if it may be determined that the first light field distribution is as shown in FIG. 2B and the expected pattern distribution is a pattern having a uniform duty cycle as shown in FIG. 2A, then in a case that the floodlight source and the laser light source included in the dual-beam or multi-beam laser interference lithography device have the same wavelength, the second light field distribution may be determined based on a difference of the above-mentioned patterns. In an embodiment, an empirical table for the compensation values may be obtained through experiments, and the flood exposure dose distribution required to obtain the target duty cycle distribution may be obtained by looking up the table. Certainly, when the two do not have the same wavelength, the second light field distribution is determined by considering an impact of light at the wavelength on the first light field distribution within the interference-exposed wafer. More specifically, in a case that the expected pattern is a periodic pattern having a uniform duty cycle, a higher flood exposure dose is applied at a location with a smaller first light field distribution (i.e., an interference exposure dose is small), and a lower flood exposure dose is applied at a location with a larger first light field distribution (i.e., an interference exposure dose is large), as shown in FIG. 2C.

Alternatively, the apparatus of laser interference lithography according to exemplary embodiments of the present disclosure may additionally include a developing unit configured to develop the flood-exposed wafer.

The above shows an apparatus of laser interference lithography according to exemplary embodiments of the present disclosure, and the apparatus of laser interference lithography compensates for the interference exposure by using patterned flood exposure, that is, determining the light field distribution of the floodlight source based on the first light field distribution obtained after the interference exposure, and performing flood exposure compensation based on this, which may achieve any given lithography pattern, and the like, i.e., being able to controllably provide the expected lithography pattern with high accuracy, without significantly increasing the complexity and manufacturing cost of the device. The interference lithography pattern formed may be a one-dimensional grating structure, or a two-dimensional lattice, hole array, and other structures. Applications of the resulting patterns include a distributed feedback (DFB) laser, a field emission display (FED), a liquid crystal display (LCD), an advanced data storage application, a grating, a metric, and a Moth-Eye sub wavelength structure (SWS), and the like.

It should be noted that although the above description describes components included in the apparatus of laser interference lithography in a discrete form according to exemplary embodiments of the present disclosure, the above-mentioned components may be formed discretely or integrated into a system. In addition, the above-mentioned components may also be divided into a plurality of components or combined into one or more components without affecting the implementation of the present disclosure.

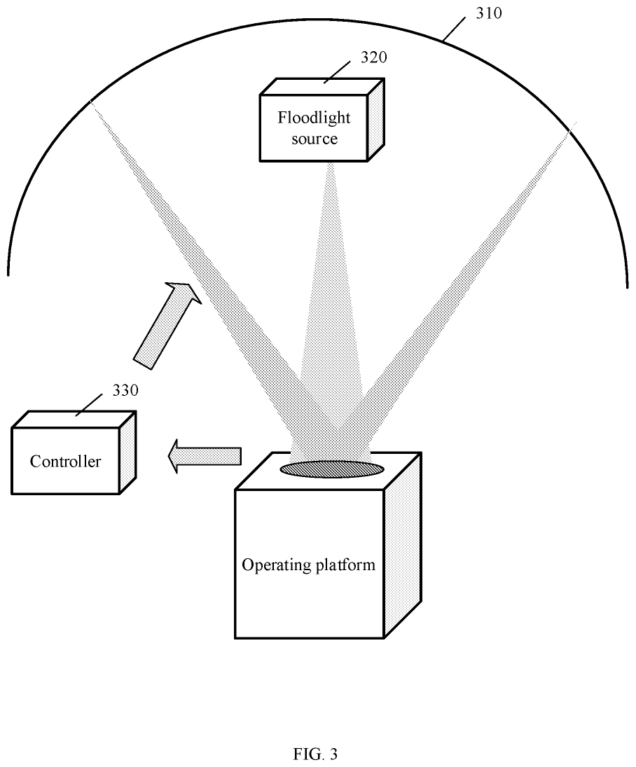

FIG. 4 shows a flowchart of a method of laser interference lithography according to exemplary embodiments of the present disclosure. The method of laser interference lithography according to exemplary embodiments of the present disclosure may generally include the following operations: in operation S410, an interference exposure is performed on a wafer coated with photoresist; in operation S420, patterned flood exposure is performed on the interference-exposed wafer. In a preferred embodiment, after coating the photoresist, a homogenization treatment may be additionally performed to evenly coat the photoresist. In addition, the method of laser interference lithography may also include performing a development processing, that is, performing the development processing on the flood-exposed wafer to ultimately provide the expected lithographic pattern.

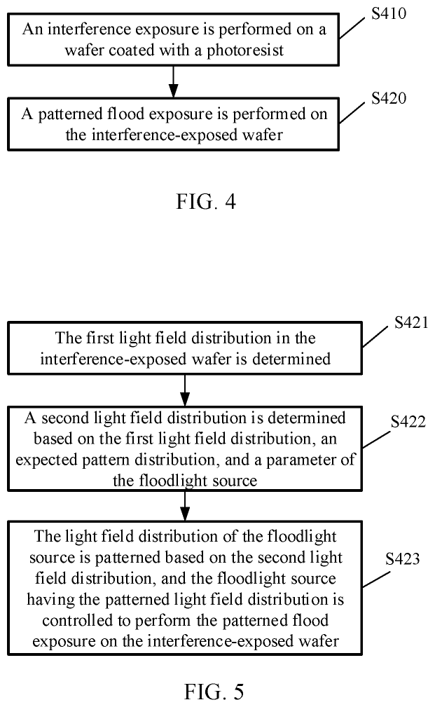

FIG. 5 shows a flowchart of a flood exposure process according to exemplary embodiments of the present disclosure. Specifically, the operation S420 of performing flood exposure may further include operation S421 to operation S423.

In operation S421, the first light field distribution in the interference-exposed wafer is determined. As described above, the determining the first light field distribution may include: developing an interference-exposed sample using a developing device; detecting a profile of the developed wafer through a detection instrument such as a scanning electron microscope; and determining the first light field distribution in the interference-exposed wafer based on the detected profile.

In operation S422, a light field distribution of the floodlight source is determined as a second light field distribution based on the first light field distribution, an expected pattern distribution, and parameters of the floodlight source used for the floodlight exposure. In a case that the expected pattern distribution is a periodic pattern having a uniform duty cycle, the determining the second light field distribution includes applying a higher flood exposure dose at a location with a smaller first light field distribution (i.e., an interference exposure dose is small), and applying a lower flood exposure dose at a location with a larger first light field distribution (i.e., an interference exposure dose is large). However, in a case that the expected pattern distribution is a pattern distribution having a spatially modulated duty cycle, the second light field distribution may be determined such that the pattern distribution having a spatially modulated duty cycle is formed in the flood-exposed wafer.

In operation S423, the light field distribution of the floodlight source is patterned based on the second light field distribution, and the floodlight source having the patterned light field distribution is controlled to perform patterned flood exposure on the interference-exposed wafer, so as to form the expected pattern distribution in the flood-exposed wafer. For example, when a light field patterning module such as a spatial light modulator is configured in the floodlight source, the light field distribution of the floodlight source may be patterned via the light field patterning module into the second light field distribution.

It may be seen that the method of laser interference lithography according to exemplary embodiments of the present disclosure compensates for the interference exposure by using the flood exposure, that is, determining the light field distribution of the floodlight source based on the first light field distribution obtained after the interference exposure, and performing flood exposure compensation based on this, which may achieve any given lithography pattern, and the like, i.e., being able to controllably provide the expected lithography pattern with high accuracy, without significantly increasing the complexity and manufacturing cost of the device. The interference lithography pattern formed by using the apparatus and method shown in exemplary embodiments of the present disclosure may be may be a one-dimensional grating structure, or a two-dimensional lattice, hole array, and other structures. Applications of the resulting patterns include a distributed feedback (DFB) laser, a field emission display (FED), a liquid crystal display (LCD), an advanced data storage application, a grating, a metric, and a Moth-Eye sub wavelength structure (SWS), and the like.

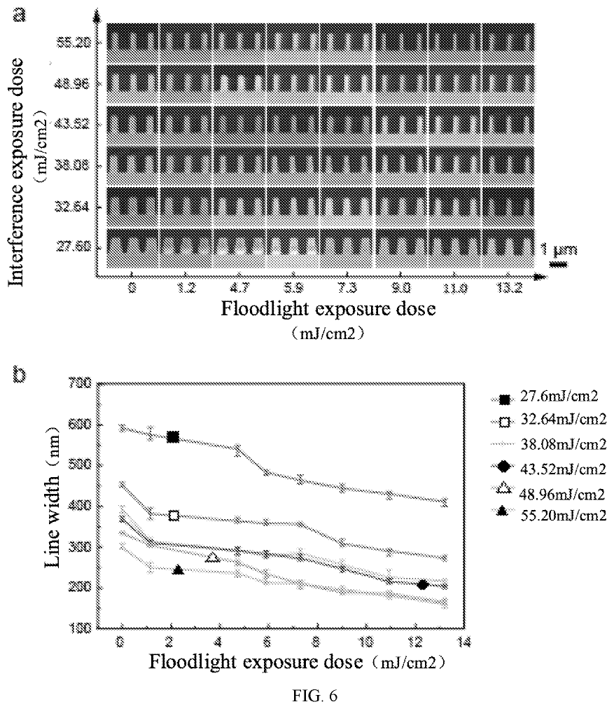

FIG. 6 to FIG. 11 show examples of applying the method and apparatus according to exemplary embodiments of the present disclosure, respectively.

FIG. 6 shows a grating-like structure having a period of, for example, 1 μm formed using an apparatus and a method of laser interference lithography according to exemplary embodiments of the present disclosure. In experimental studies on structures with the same period, as shown in figure a in FIG. 6, an exposure dose of the interference pattern is gradually increased in a step of 4.6 mJ/cm² from 27.6 mJ/cm² to 55.2 mJ/cm², and the exposure dose of the floodlight source is gradually increased from 0 mJ/cm² to 13.2 mJ/cm². Electron microscopic images of the grating-like structure are observed at different interference exposure doses and floodlight exposure doses, and it may be found that increasing the interference exposure dose and/or the floodlight exposure dose will reduce a line width. However, under different initial interference exposure doses, there will be different line width modulation ranges, wherein a lower initial interference exposure dose will result in a larger line width modulation range, as shown in figure b in FIG. 6. For example, a gradual increase in the exposure dose of the floodlight source from 0 mJ/cm² to 13.2 mJ/cm² may produce a line width change of about 180 nm for a grating-like structure initially exposed at 27.6 mJ/cm², while only produce a line width change of about 140 nm for a grating-like structure initially exposed at 55.2 mJ/cm².

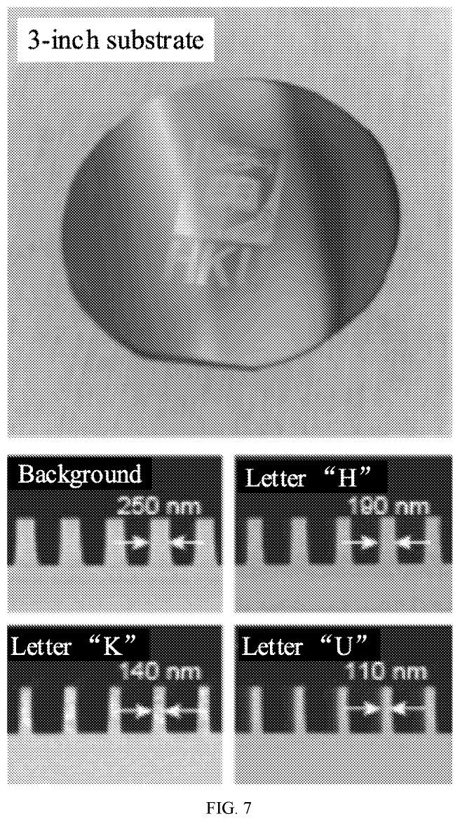

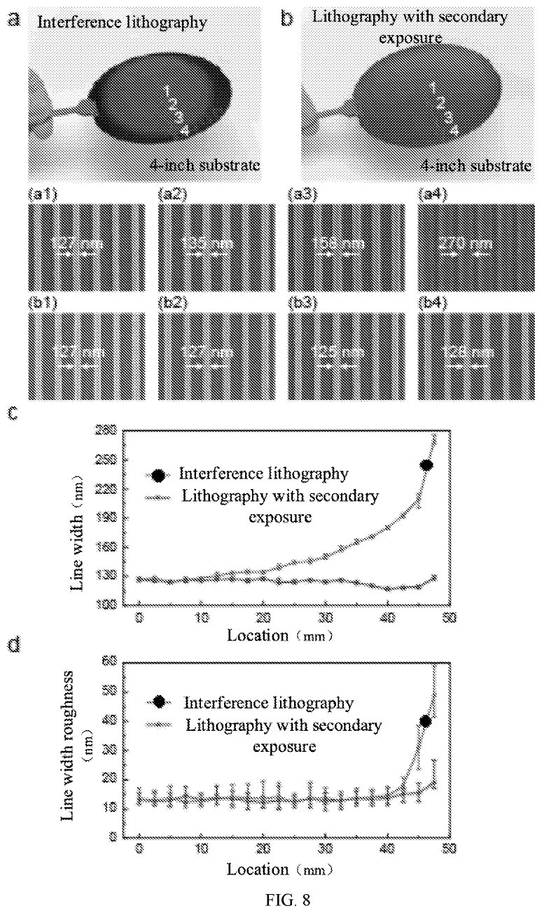

FIG. 7 and FIG. 8 show schematic diagrams of performing a secondary exposure using a dual-beam or multi-beam laser interference lithography device having an ideal interference pattern and a floodlight source having a patterned distribution.

FIG. 7 shows a sample diagram of a pattern having a spatially modulated duty cycle fabricated on a 3-inch sample using an apparatus and a method of laser interference lithography according to exemplary embodiments of the present disclosure, and electron microscope scanning diagrams of positions corresponding to a background, a letter “H”, a letter “K”, and a letter “U” on the 3-inch sample, respectively. The period of the grating-like structure on the wafer is 600 nm, but four line-widths exist. Specifically, a line width of the grating-like structure located in the background is 250 nm, a line width of the grating-like structure located at the letter “H” is 190 nm, a line width of the grating-like structure located at the letter “K” is 140 nm, and a line width of the grating-like structure located at the letter “U” is 110 nm.

FIG. 8 shows an example of obtaining a grating-like structure having uniform line width on a large size wafer using a method and apparatus according to exemplary embodiments of the present disclosure. When processing the large size wafer using the dual-beam or multi-beam laser interference lithography device having an ideal interference pattern, a distribution of the interference pattern on the wafer may deviate from the ideal interference pattern due to various reasons such as a larger size of the wafer or a performance of the interference light source. Therefore, it is possible to cause a resulting grating-like structure to have an uneven line width. Based on the concept of the present disclosure, in this case, a patterned floodlight source may be used to perform the secondary exposure for compensation.

For example, figure a in FIG. 8 shows a schematic diagram of performing lithography on a large size wafer (e.g., 4-inch) using only interferometric holography, and its electron microscope scanning images (figure (a1) to figure (a4)) fully demonstrate that a width of the fabricated grating-like structure is widened from 127 nm to 270 nm. In contrast, figure b shows a schematic diagram of performing lithography on a large size wafer using a lithography method according to exemplary embodiments of the present disclosure, and its electron microscope scanning diagrams (figure (b1) to figure (b4) fully demonstrate that a width of the fabricated grating-like structure is basically maintained at 127 nm. Figure c and figure d show a line width and line width roughness of a grating-like structure on a 4-inch wafer as a function of position, respectively.

It may be seen from the above that by using the lithography method according to exemplary embodiments of the present disclosure, a line width deviation of the grating-like structure may be reduced from 36.2 nm to 3.2 nm. In addition, the line width roughness is also significantly improved, especially for grating-like structures near an edge of the wafer.

In addition to patterning a large area and uniformly distributed grating-like structure, the apparatus and the method of laser interference lithography according to exemplary embodiments of the present disclosure may also spatially modulate a filling rate of a two-dimensional nanostructure.

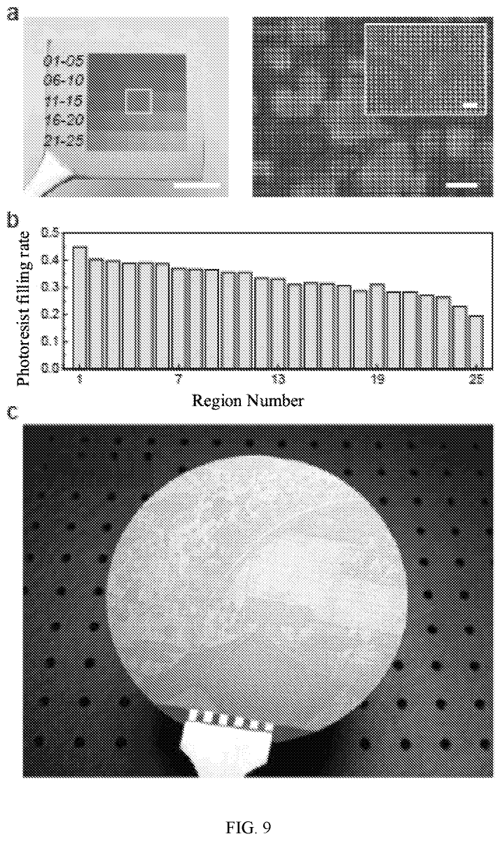

FIG. 9 shows an example of spatially modulating a filling rate of a two-dimensional nanostructure using a method and apparatus according to exemplary embodiments of the present disclosure. A two-dimensional pattern with a period of 700 nm is exposed on a back of a silicon oxide wafer, and then the filling rate is adjusted by using a grayscale image composed of 25 grayscale values, wherein 25 grayscale values represent different exposure doses. Figure a shows a photograph of a developing substrate and an electron microscope image of a marking region, wherein when the grayscale value used for secondary exposure increases from 0 to 240, the color in 5×5 units gradually changes from brown to gold, and the substrate includes a two-dimensional nanostructure with a 700 nm cycle, and has various filling rates that are adjusted by the grayscale pattern secondary exposure. Figure b shows photoresist filling rates of 25 regions in the figure a. As may be seen from figure b, the photoresist filling rate decreases as a dose used for secondary exposure increases. Figure c shows a depiction of a fine painting on a 3-inch wafer. It may be seen that the apparatus and method according to exemplary embodiments of the present disclosure may effectively spatially modulate the filling rate of two-dimensional nanostructure.

As shown in FIG. 7 to FIG. 9, the apparatus and method of laser interference lithography according to exemplary embodiments of the present disclosure may be applied to manufacture patterns having spatially modulated duty cycles, which may break through an application limitation of the apparatus and the method of laser interference lithography. Based on this, the existing interference lithography system may be improved to produce the expected nanostructure with or without periodicity over a large area.

In addition, it should be noted that the present disclosure describes the inventive concept in an order of performing patterned flood exposure after performing the interference exposure. However, it should be clear to those skilled in the art that the order of performing the interference exposure and performing patterned exposure may be reversed, that is, the interference exposure may be performed after performing flood exposure. In addition, the two may also be basically executed simultaneously. The flowcharts and block diagrams in the drawings illustrate the architecture, functionality, and operation of possible implementations of systems, methods and computer program products according to various embodiments of the present disclosure. In this regard, each block in the flowcharts or block diagrams may represent a module, program segment, or portion of code, which contains one or more executable instructions for implementing the specified logical function. It should also be noted that, in some alternative implementations, the functions noted in the blocks may occur out of the order noted in the drawings. For example, two blocks shown in succession may, in fact, be executed substantially concurrently, or the two blocks may sometimes be executed in a reverse order, depending upon the functionality involved. It should also be noted that each block of the block diagrams or flowcharts, and combinations of the blocks in the block diagrams or flowcharts, may be implemented by using a special purpose hardware-based system that performs the specified functions or operations, or may be implemented using a combination of a special purpose hardware and computer instructions.

Those skilled in the art may understand that while the present disclosure has been illustrated and described with reference to specific exemplary embodiments of the present disclosure, those skilled in the art should understand that various changes in form and detail may be made to the present disclosure without departing from the spirit and scope of the present disclosure defined by the appended claims and their equivalents. Therefore, the scope of the present disclosure should not be limited to the above-mentioned embodiments, but should be determined not only by the appended claims, but also by the equivalents of the appended claims.

What is claimed is:

1. An apparatus of laser interference lithography, comprising:
a dual-beam or multi-beam laser interference lithography device configured to perform an interference exposure on a wafer coated with a photoresist;
a floodlight source having a patternable light field distribution and configured to perform a patterned flood exposure on the interference-exposed wafer; and
a controller configured to:
determine a first light field distribution in the interference-exposed wafer;
determine a light field distribution of the floodlight source as a second light field distribution based on the first light field distribution, an expected pattern distribution, and parameters of the floodlight source; and
pattern the light field distribution of the floodlight source based on the second light field distribution, and control the floodlight source having the patterned light field distribution to perform the patterned flood exposure on the interference-exposed wafer, so as to form the expected pattern distribution in the flood-exposed wafer.

2. The apparatus according to claim 1, wherein the floodlight source further comprises a defocusing module configured to defocus light emitted by the floodlight source to form a flooded blurred spot.

3. The apparatus according to claim 1, wherein the floodlight source further comprises a motor configured to move the floodlight source slightly to form a flooded blurred spot.

4. The apparatus according to claim 1, wherein the floodlight source further comprises a light field patterning module, and
wherein the controller is further configured to pattern the light field distribution of the floodlight source via the light field patterning module into the second light field distribution.

5. The apparatus according to claim 1, further comprising a developing unit configured to develop the flood-exposed wafer.

6. The apparatus according to claim 1, wherein a patterned floodlight source is implemented using a grayscale image from a UV projector, wherein different grayscale values in the grayscale image represent different light intensities.

7. The apparatus according to claim 1, wherein the first light field distribution is an ideal interference pattern, and the second light field distribution is a uniform distribution.

8. The apparatus according to claim 1, wherein the first light field distribution is an ideal interference pattern, and the second light field distribution is a stepped distribution.

9. A method of laser interference lithography, comprising:
performing an interference exposure on a wafer coated with a photoresist; and
performing a patterned flood exposure on the interference-exposed wafer,
wherein the performing a patterned flood exposure comprises:
determining a first light field distribution in the interference-exposed wafer;
determining a light field distribution of the floodlight source as a second light field distribution based on the first light field distribution, an expected pattern distribution, and parameters of the floodlight source used for the patterned flood exposure; and
patterning the light field distribution of the floodlight source based on the second light field distribution, and controlling the floodlight source having the patterned light field distribution to perform the patterned flood exposure on the interference-exposed wafer, so as to form the expected pattern distribution in the flood-exposed wafer.

10. The method according to claim 9, further comprising performing a development processing on the flood-exposed wafer.

11. The method according to claim 9, wherein the determining a first light field distribution comprises:
developing an interference-exposed sample;
detecting a profile of the developed wafer through a scanning electron microscope; and
determining the first light field distribution in the interference-exposed wafer based on the detected profile.

12. The method according to claim 9, wherein the determining the second light field distribution comprises: determining to apply a higher flood exposure dose at a location with a smaller first light field distribution and to apply a lower flood exposure dose at a location with a larger first light field distribution, in response to determining the expected pattern distribution to be a periodic pattern having a uniform duty cycle.

13. The method according to claim 9, wherein the determining the second light field distribution comprises: determining the second light field distribution in response to determining the expected pattern distribution to be a pattern distribution having a spatially modulated duty cycle, so that the pattern distribution having the spatially modulated duty cycle is formed in the flood-exposed wafer.

14. The method according to claim 9, wherein a patterned floodlight source is implemented using a grayscale image from a UV projector, wherein different grayscale values in the grayscale image represent different light intensities.

15. The method according to claim 9, wherein the first light field distribution is an ideal interference pattern, and the second light field distribution is a uniform distribution.

16. The method according to claim 9, wherein the first light field distribution is an ideal interference pattern, and the second light field distribution is a stepped distribution.
